(19) United States
(12) Patent Application Publication
(10) Pub. No.: US 2023/0164987 A1
(43) Pub. Date: May 25, 2023

(54) 3D NAND MEMORY CELL WITH FLAT TRAP BASE PROFILE

(71) Applicant: Intel Corporation, Santa Clara, CA (US)

(72) Inventors: Linlin SUN, Liaoning (CN); Jie LI, Boise, ID (US); Jin LU, Liaoning (CN); Jialin MA, Liaoning (CN); Junmin CHOI, Liaoning (CN); Yu YUWEN, Albuquerque, NM (US)

(73) Assignee: Intel Corporation, Santa Clara, CA (US)

(21) Appl. No.: 17/551,018

(22) Filed: Dec. 14, 2021

Related U.S. Application Data
(63) Continuation of application No. PCT/CN2021/132056, filed on Nov. 22, 2021.

(51) Int. Cl. H01L 27/11556; H01L 29/423; G11C 5/02; H01L 29/788; G11C 5/06; H01L 29/66

(52) U.S. Cl. CPC H01L 27/11556; H01L 29/42324; G11C 5/025; H01L 29/7889; G11C 5/06; H01L 29/66825

(57) ABSTRACT

An embodiment of an apparatus may include a substrate with alternated layers of conductor material and insulator material, a vertical channel through at least four of the alternated layers of the substrate, where an edge of the layers of insulator material abuts an edge of the vertical channel, and a memory cell on the vertical channel disposed in a layer of conductor material between two layers of the insulator material, where the memory cell comprises a control gate disposed in a recess of the layer of conductor material between the two layers of the insulator material, a trap base disposed in the recess between the control gate and the edge of the vertical channel, and tunnel oxide material that covers the trap base and extends into the vertical channel outside of the recess and beyond the edge of the two layers of insulator material. Other embodiments are disclosed and claimed.

### CLAIM FOR PRIORITY

This application claims priority to International Patent Application No. PCT/CN2021/132056, filed Nov. 22, 2021 and titled “3D NAND MEMORY CELL WITH FLAT TRAP BASE PROFILE,” which is incorporated by references in its entirety for all purposes.

### BACKGROUND

A typical flash memory device may include a memory array that includes a large number of non-volatile memory cells arranged in row and column fashion. In recent years, vertical memory, such as three-dimensional (3D) memory, has been developed in various forms, such as NAND, cross-point, or the like. A 3D flash memory array may include a plurality of memory cells stacked over one another to form a vertical NAND string. In a floating gate flash cell, a conductive floating gate may be positioned between a control gate and a channel of a transistor. The individual memory cells of the vertical NAND string may be on different layers arranged around a body that extends outward from a substrate, with the conductive floating gate (charge storage region) located on a similar or same plane as the control gate, extending outward horizontally from the body.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is an illustrative diagram of an example of an apparatus according to an embodiment;

FIGS. 2A to 2D are illustrative diagrams of an example of a method according to an embodiment;

FIGS. 3A to 3E are illustrative diagrams of an example of a process according to an embodiment;

FIGS. 4A to 4B are illustrative diagrams of another example of a process according to an embodiment; and

FIG. 5 is a block diagram of an example of a computing system according to an embodiment.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

While the following description sets forth various implementations that may be manifested in architectures such as system-on-a-chip (SoC) architectures for example, implementation of the techniques and/or arrangements described herein are not restricted to particular architectures and/or computing systems and may be implemented by any architecture and/or computing system for similar purposes. For instance, various architectures employing, for example, multiple integrated circuit (IC) chips and/or packages, and/or various computing devices and/or consumer electronic (CE) devices such as set top boxes, smartphones, etc., may implement the techniques and/or arrangements described herein. Further, while the following description may set forth numerous specific details such as logic implementations, types and interrelationships of system components, logic partitioning/integration choices, etc., claimed subject matter may be practiced without such specific details. In other instances, some material such as, for example, control structures and full software instruction sequences, may not be shown in detail in order not to obscure the material disclosed herein.

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

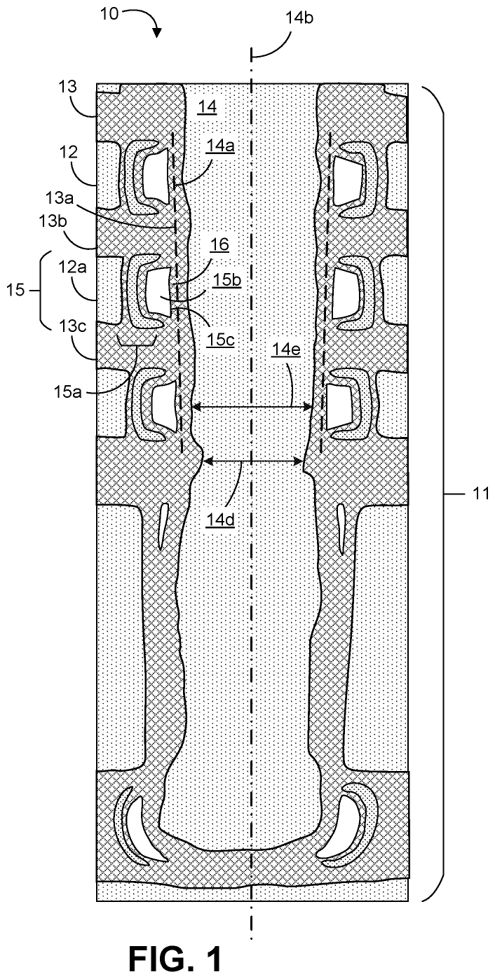

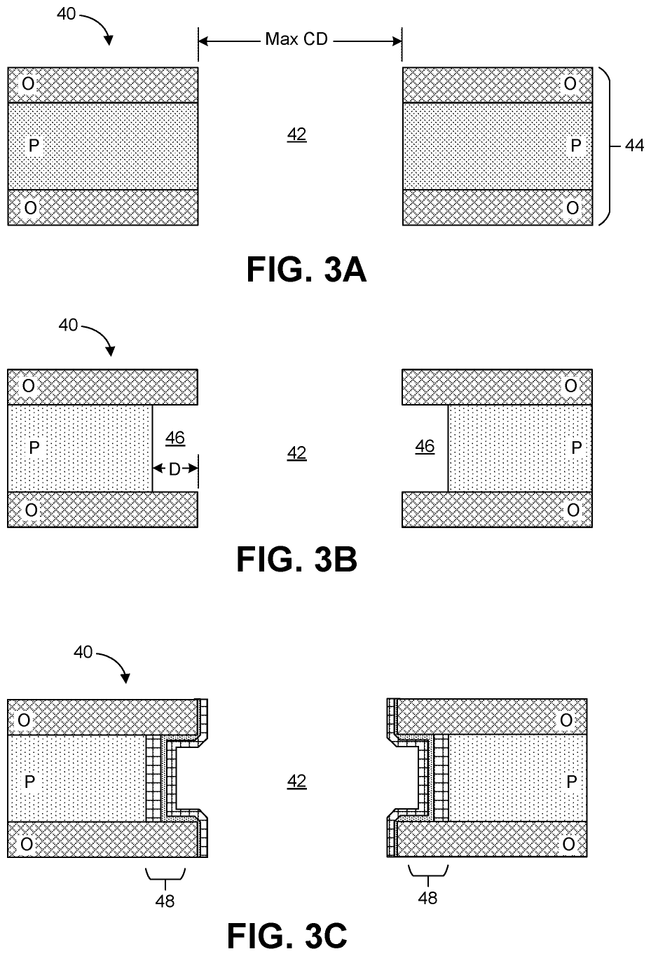

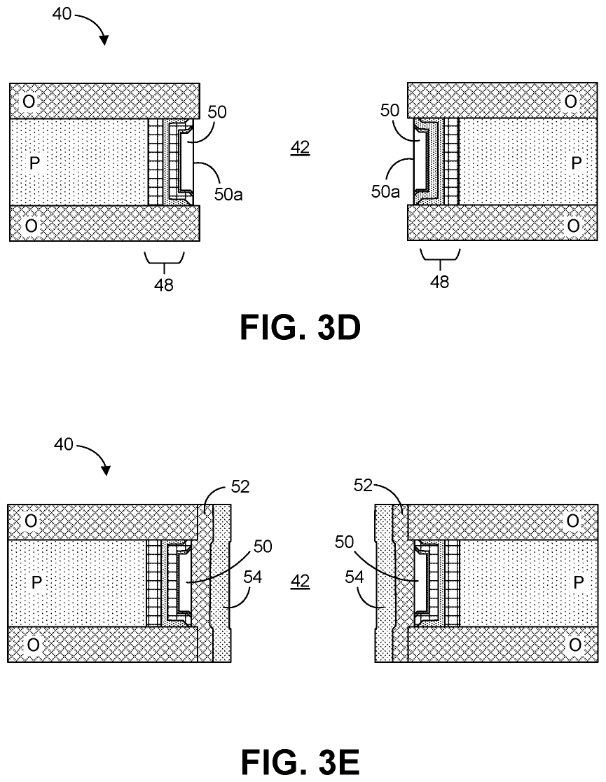

With reference to FIG. 1, an embodiment of an apparatus 10 may include a substrate 11 with alternated layers of conductor material 12 and insulator material 13, a vertical channel 14 through at least four of the alternated layers of the substrate 11, where an edge 13a of the layers of insulator material 13 abuts an edge 14a of the vertical channel 14. The apparatus 14 further includes a memory cell 15 on the vertical channel 14 disposed in a layer of conductor material 12a between two layers 13b and 13c of the insulator material. As shown in FIG. 1, the memory cell 15 may comprise a control gate 15a disposed in a recess of the layer 12a of conductor material 12 between the two layers 13b and 13c of the insulator material 13 (e.g., see FIG. 3B), a trap base 15b disposed in the recess between the control gate 15a and the edge 14a of the vertical channel 14, and tunnel oxide material 16 that covers the trap base 15b and extends into the vertical channel 14 outside of the recess and beyond the edge 13a of the two layers 13b and 13c of insulator material. For example, FIG. 1 shows a cross section taken through a center line axis 14b of the vertical channel 14 and a center of the memory cell 15. As shown in FIG. 1, the cross section has a substantially flat front line 15c in profile for the trap base 15b parallel to the vertical channel 14.

As further shown in FIG. 1, the material adjacent to the edge 14a of the vertical channel 14 has substantially straight edges with little waviness. For example, a measurement of waviness may indicate a range of variation from a straight edge or mean of variation from the straight edge. The measured variation may correspond to a difference between adjacent peaks and valleys of the surface. For example, a conventional memory cell may have a trap base with a concave profile adjacent to the vertical channel that results in waviness along the vertical length of the vertical channel, where a peak measurement corresponds to a widest width of the material adjacent to the edge of the vertical channel between opposed concave profiles of the trap base and a valley measurement corresponds to a narrowest width of the material adjacent to the edge of the vertical channel at the layer of insulator material above the trap base. A conventional memory cell may exhibit a waviness of about 1 unit (e.g., an arbitrary unit for relative reference) with a range of variation of more than one hundred and seventy percent (170% from peak to valley). With the substantially flat trap base profiles, embodiments further exhibit much less waviness in the vertical channel. For example, some embodiments may exhibit no substantial range of variation between peaks and valleys of the material (e.g., less than about 10% variation). For example, material adjacent to the edge 14a of the vertical channel 14 may have a mean waviness of about 0.88 unit with a range of variation for the vertical channel 14 that is less than one hundred and thirty percent (130% from measured peak to measured valley).

Advantageously, the improved waviness may provide benefits in terms of electrical characteristics of the memory cell. For example, a read window budget (RWB) gain for the memory cell may be in a range of between 200 millivolts and 500 millivolts.

As further shown in FIG. 1, the vertical channel 14 has improved necking at the bottom tapered end of the vertical channel 14. For example, material adjacent to outside edges of the vertical channel 14 tapers to a pinch point 14d that is at least twenty nine percent larger for embodiments as compared to conventional materials/techniques. Advantageously, the improved necking may provide benefits in terms of electrical characteristics of the memory cell. For example, a control gate voltage (Vg) minus a threshold voltage (Vt) of a programmed memory cell within the vertical channel may be in a range of between 300 millivolts and 450 millivolts.

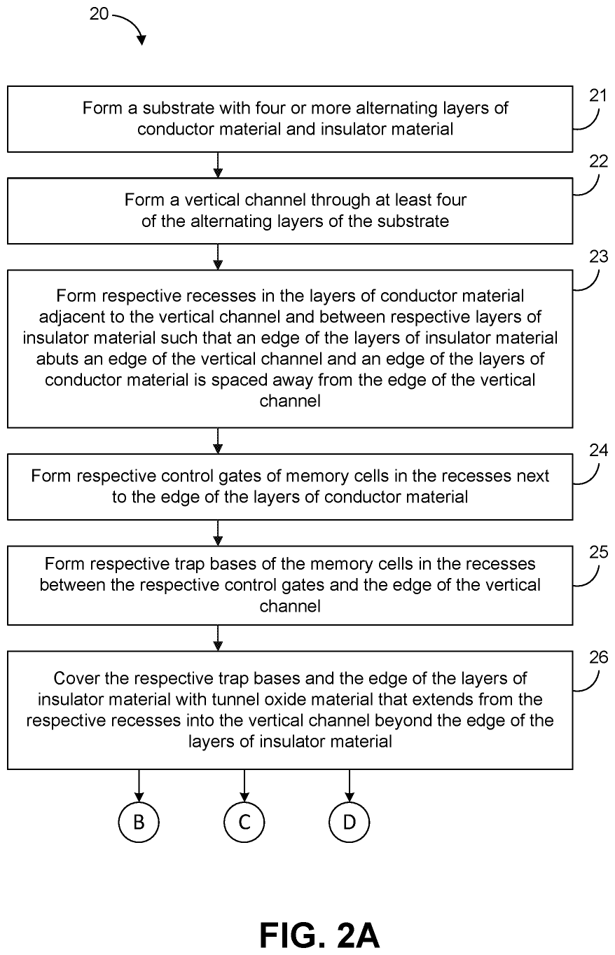

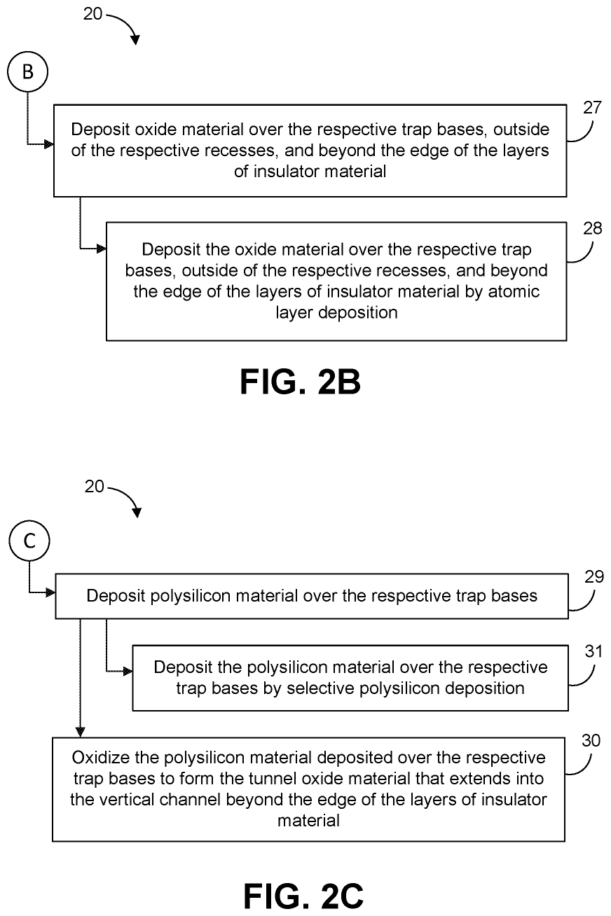

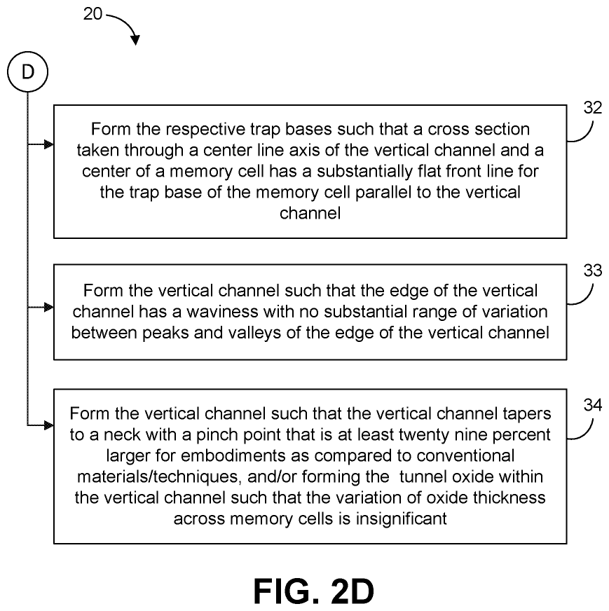

With reference to FIGS. 2A to 2D, an embodiment of a method 20 may include forming a substrate with four or more alternating layers of conductor material and insulator material at box 21, forming a vertical channel through at least four of the alternating layers of the substrate at box 22, forming respective recesses in the layers of conductor material adjacent to the vertical channel and between respective layers of insulator material such that an edge of the layers of insulator material abuts an edge of the vertical channel and an edge of the layers of conductor material is spaced away from the edge of the vertical channel at box 23, forming respective control gates of memory cells in the recesses next to the edge of the layers of conductor material at box 24, forming respective trap bases of the memory cells in the recesses between the respective control gates and the edge of the vertical channel at box 25, and covering the respective trap bases and the edge of the layers of insulator material with tunnel oxide material that extends from the respective recesses into the vertical channel beyond the edge of the layers of insulator material at box 26.

Some embodiments of the method 20 may further include depositing oxide material over the respective trap bases, outside of the respective recesses, and beyond the edge of the layers of insulator material at box 27. For example, the method 20 may include depositing the oxide material over the respective trap bases, outside of the respective recesses, and beyond the edge of the layers of insulator material by atomic layer deposition at box 28.

Alternatively, some embodiments of the method 20 may include depositing polysilicon material over the respective trap bases at box 29, and oxidizing the polysilicon material deposited over the respective trap bases to form the tunnel oxide material that extends into the vertical channel beyond the edge of the layers of insulator material at box 30. For example, the method 20 may include depositing the polysilicon material over the respective trap bases by selective polysilicon deposition at box 31.

Some embodiments of the method 20 may further include forming the respective trap bases such that a cross section taken through a center line axis of the vertical channel and a center of a memory cell has a substantially flat front line for the trap base of the memory cell parallel to the vertical channel at box 32, forming the vertical channel such that the edge of the vertical channel has a waviness with no substantial range of variation between peaks and valleys of the edge of the vertical channel at box 33 (e.g., with a range of variation for the vertical channel that is forty percent improved and a mean for the vertical channel that is twelve percent tighter), forming the vertical channel such that the vertical channel tapers to a neck with a pinch point that is at least twenty nine percent larger for embodiments as compared to conventional materials/techniques, and/or forming the tunnel oxide within the vertical channel such that the variation of oxide thickness across memory cells is insignificant at box 34 (e.g. with a variation for the oxide uniformity improved more than thirty percent).

Some embodiments provide process technology to integrate a memory cell to relax a pillar etch maximum critical dimension (CD) and resolve a necking CD issue. As 3D NAND scales to more tiers, higher oxide-poly-oxide-poly (OPOP) stacks need to be etched and the higher OPOP stacks provide challenges with respect to the pillar max CD, taper, notching, and necking. Moreover, taller OPOP stacks also indirectly increase the within pillar (WiP) and within wafer nonuniformity of cell films because of varying surface area at different WLs and across the wafer. In general, a smaller max CD results in more problems with the taper, notching, and necking. For example, when the bottom CD gets too small, the trap base and channel film will have a necking issue at the pillar bottom. As to the cell formation, the pillar profile impacts many metrics including: 1) conformality of cell films such as, for example, Tunnel Oxide/trap base thickness/channel thickness and electrical CD (E-CD) taper; 2) trap base shape and interface profile; and 3) channel waviness. Some embodiments advantageously overcome one or more of the foregoing problems.

Some embodiments may advantageously provide one or more of improved pillar etch uniformity, improved cell films uniformity, and improved reliability. Some embodiments may improve a process margin of pillar etch with an embodiment of a memory cell integration flow where the max CD is relaxed so that the pillar etch may provide improved taper/notching/bottom CD (e.g., and other metrics) and where a doped hollow channel (DHC)-DHC E-CD loss (e.g., due to max CD relaxation (MCR)) is compensated through other aspects of the cell formation flow.

In an embodiment of a cell integration MCR flow, a pillar etch Max CD is relaxed (e.g., increased) and a control gate recess (CGR) may be backed-off (e.g., decreased) to maintain a same overall control gate (CG) size for a desired memory cell configuration. For example, the Max CD may be increased by about 10% and the CGR may be decreased by about 20%. For example, the cell integration may utilize a process flow for the memory cell configuration to meet a properly tuned targets such as, for example, sacrificial silicon/trap base Tetramethylammonium Hydroxide (TMAH) cut and tunnel oxide (TunOx) formation. In some embodiments, tunnel oxide may be formed out of the memory cell pocket to compensate the CD loss due to the max CD relaxation. For example, the TunOx formation may utilize a high quality deposition process such as Atomic Layer Deposition Oxide (ALD Ox), poly seeding plus oxidation, etc. Advantageously, memory devices fabricated in accordance with embodiments of the process flow described herein may exhibit improved structural results and/or improved memory cell electrical characteristics and reliability.

In some embodiments, a starting pillar etch max CD is larger, but a final max CD is smaller after cell formation. Advantageously, a CD uniformity across the memory cells may be improved due to a taper improvement. In particular, for a bottom four WLs (WL0 to WL3) the taper improves significantly and advantageously leads to a within pillar (WiP) gain and widens the cell formation margin to prevent pinch-off or punch under etch (UE) that might be caused by a smaller bottom WL CD. Due to larger bottom WL CD of an embodiment of the MCR flow described herein, for example, pillar bottom WL necking may also show significant improvements for DHC deposition.

With respect to the memory cell, TunOx formation may be independent on the substrate (e.g., better step coverage (S/C)) and some embodiments may resolve the Bird's beak (e.g., by enlarging a length between DHC and flank nitride (DHC-FN_L)). Advantageously, TunOx within the pillar uniformity may show substantial improvement in some embodiments. The DHC deposition will have a uniform substrate and then a better waviness and roughness. The DHC— DHC CD will be smaller than a conventional memory cell with the relaxed max CD and a program and erase (P/E) window may benefit.

With respect to electrical specifications (E-SPECs), embodiment of a poly seeding (e.g., with selective poly deposition) plus oxidation process results in a suitable TunOx structure. Advantageously, reliability may improve because endurance/Single Bit Charge Loss (SBCL)/etc. may be better due to a straighter trap base (TB)/TunOx interface in the MCR flow;

With reference to FIG. 3A, an embodiment of a process 40 includes forming a pillar 42 through an OPOP substrate 44. FIG. 3A only shows one layer of poly (P) between two layers of oxide (O), but those skilled in the art will appreciate that a 3D NAND string will include many more such alternating layers of oxide and poly with the pillar 42 formed therethrough. A max CD for the pillar 42 is relaxed to be about 10% more than a max CD for a conventional memory device. Any suitable technique may be utilized to form the substrate 44 with the pillar 42 therethrough.

With reference to FIG. 3B, the process 40 next includes forming a CGR 46 in the poly layer. The CGR 46 may extend inward from the pillar 42 by a depth amount D that is about 20% less than the depth of the CGR for a conventional memory device. Any suitable techniques may be utilized to form the CGR 46 at a suitable depth D.

With reference to FIG. 3C, the process 40 next includes forming a set of interpoly dielectric (IPD) films from a control gate 48 in the CGR 46. Any suitable techniques may be utilized to form the control gate 48.

With reference to FIG. 3D, the process 40 next includes forming a trap base 50 in the CGR 46 on the dielectric films of the control gate 48. With the process 40, a thickness of the trap base (rTB_T) may start thinner as compared to an rTB_T for a trap base formed in a conventional CGR after rTB oxide hydrogen fluoride (HF) cut (e.g., for a same rTB oxide), because conventionally a tunnel oxide that covers the trap base is formed by consuming the trap base material to form the tunnel oxide inside the pocket of the conventional CGR.

With reference to FIG. 3E, the process 40 next includes covering the trap base 50 with tunnel oxide 52 that extends outside the pocket of the CGR 46. For example, as shown in FIG. 3E, the tunnel oxide 52 may be deposited in the pillar 42 to cover the trap base 50. Advantageously, depositing the tunnel oxide 52 does not consume the material of the trap base 50 (e.g., rTB is not consumed) and the Bird's beak of the trap base 50 that faces the pillar 42 remains substantially small in profile. As noted above, the DHC-DHC CD of the tier oxide (O) from the OPOP stack is smaller (e.g., as compared to a conventional memory device), but the CD of tier poly (P) of this embodiment of the process 40 for MCR is the same such that rTB_T is matched and suitable for the desired memory cell configuration. In accordance with some embodiments, a high quality deposition process, such as high temperature ALD, is utilized to deposit the tunnel oxide 52. As shown in FIG. 3E, additional material 54 may be formed in the pillar 42 over the tunnel oxide 52.

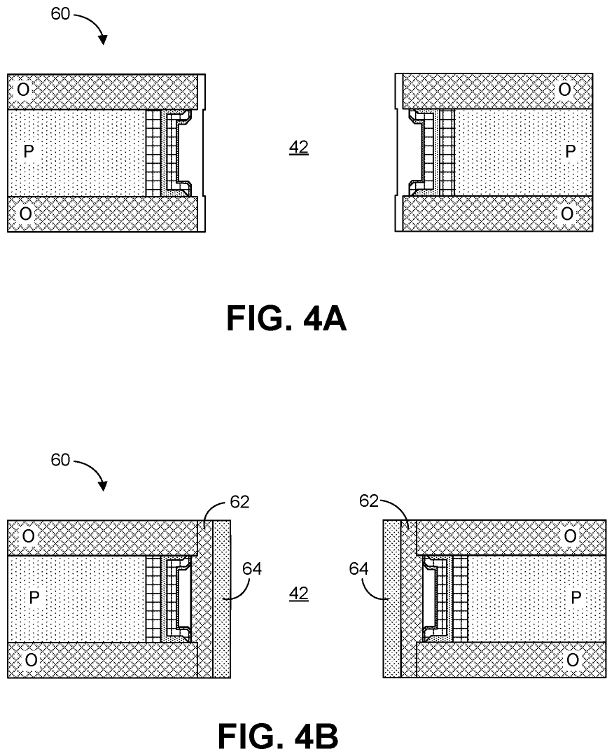

With reference to FIG. 4A, instead of ALD, an embodiment of a process 60 may alternatively include depositing the tunnel oxide by a poly seeding plus oxidation process. For example, following the process 40 as described in connection with FIG. 3D, the process 60 may next include using selective poly deposition to deposit a smaller amount of poly on the tier oxide (O) as compared to an amount of poly deposited on the trap base 50 to improve channel waviness and expose the top WL nitride residual on the tier oxide (O) to subsequent oxidation process. Any suitable technique for selective poly deposition may be utilized.

With reference FIG. 4B, the process 60 next includes oxidizing the poly to form the tunnel oxide 62. As shown in FIG. 4B, additional material 64 may be formed in the pillar 42 over the tunnel oxide 62. The DHC-DHC CD (tier oxide (O)/tier poly (P) CD) of the process 60 described in connection with FIG. 3E is matched and rTB_T is also matched.

In accordance with some embodiments of an MCR process flow, rTB_T for bottom WLs may be thicker than rTB_T for a conventional memory device, and an overall mean value of rTB_T for the MCR process flow is well suited for the desired memory configuration. Some embodiments of the MCR flow may provide a TunOx Thickness (TunOx_T) that is significantly thicker as compared to a conventional memory device, and an electrical oxide thickness (EOT) may be matched through electrical learning. Because the TunOx is substrate independent, the TunOx uniformity has significant improvement as compared to a conventional memory device.

Although a starting pillar max CD is relaxed (e.g., larger), the E-CD of embodiments of the MCR flow is lower as compared to a conventional memory device at middle WLs. The bottom WL CD of the MCR flow successfully resolves a bottom necking CD issue. Some embodiments may also substantially improve CD taper after cell formation. Such structural improvements lead to a within pillar (WiP) gain, and also widen the cell formation margin to reduce or prevent pinch-off or punch UE that might otherwise be caused by a too small bottom WL CD.

Some embodiments of the MCR flow may result in a flank nitride length (FN_L) that is shorter as compared to a conventional memory device, advantageously providing better reliability. The MCR flow may also result in a distance between flank nitride and DHC (FN-DHC_D) that is larger as compared to a conventional memory device, which is better for trap up. Both FN_L and FN-DHC_D may be more uniform across the WLs from bottom to top WLs.

Embodiments of an MCR flow may also improve the TB shape from a concave face profile (e.g., a curved TB/TunOx interface) to a truer trapezoid profile (e.g., particularly embodiments of the MCR flow that utilize selective poly deposition), with a flatter face (e.g., a straight TB/TunOx interface), as shown in FIG. 1. The truer trapezoid TB shape may be better for erase and program performance and thus endurance. Embodiments of the MCR flow that result in structural improvements may also result in improvements in various electrical characteristic of the memory device. Due to taper improvements, for example, VgVt WiP range may be improved. Due to waviness reduction in the bottom WL, for example, floating gate floating gate (FGFG) may be reduces and lead to a RWB gain.

The technology discussed herein may be provided in various computing systems (e.g., including a non-mobile computing device such as a desktop, workstation, server, rack system, etc., a mobile computing device such as a smartphone, tablet, Ultra-Mobile Personal Computer (UMPC), laptop computer, ULTRABOOK computing device, smart watch, smart glasses, smart bracelet, etc., and/or a client/edge device such as an Internet-of-Things (IoT) device (e.g., a sensor, a camera, etc.)).

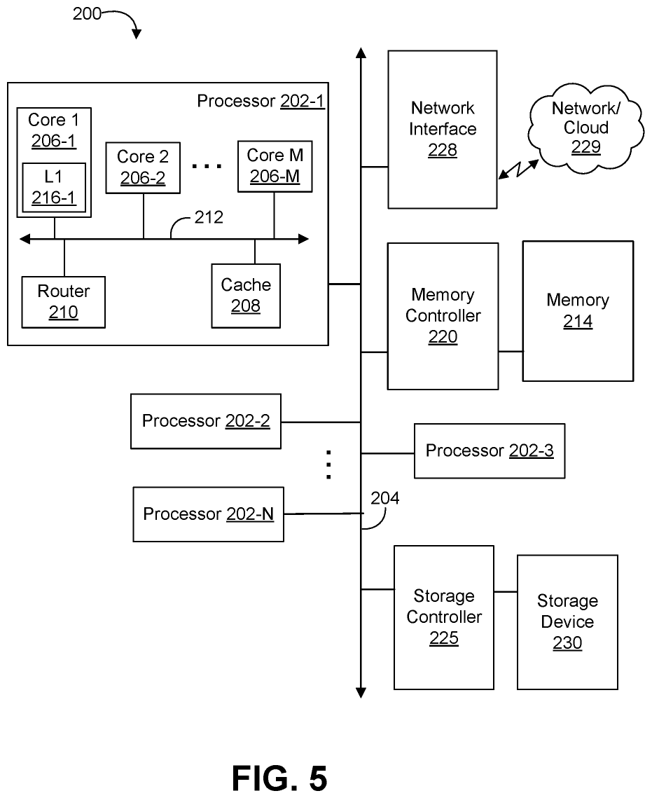

Turning now to FIG. 5, an embodiment of a computing system 200 may include one or more processors 202-1 through 202-N (generally referred to herein as “processors 202” or “processor 202”). The processors 202 may communicate via an interconnection or bus 204. Each processor 202 may include various components some of which are only discussed with reference to processor 202-1 for clarity. Accordingly, each of the remaining processors 202-2 through 202-N may include the same or similar components discussed with reference to the processor 202-1.

In some embodiments, the processor 202-1 may include one or more processor cores 206-1 through 206-M (referred to herein as “cores 206,” or more generally as “core 206”), a cache 208 (which may be a shared cache or a private cache in various embodiments), and/or a router 210. The processor cores 206 may be implemented on a single integrated circuit (IC) chip. Moreover, the chip may include one or more shared and/or private caches (such as cache 208), buses or interconnections (such as a bus or interconnection 212), memory controllers, or other components.

In some embodiments, the router 210 may be used to communicate between various components of the processor 202-1 and/or system 200. Moreover, the processor 202-1 may include more than one router 210. Furthermore, the multitude of routers 210 may be in communication to enable data routing between various components inside or outside of the processor 202-1.

The cache 208 may store data (e.g., including instructions) that is utilized by one or more components of the processor 202-1, such as the cores 206. For example, the cache 208 may locally cache data stored in a memory 214 for faster access by the components of the processor 202. As shown in FIG. 5, the memory 214 may be in communication with the processors 202 via the interconnection 204. In some embodiments, the cache 208 (that may be shared) may have various levels, for example, the cache 208 may be a mid-level cache and/or a last-level cache (LLC). Also, each of the cores 206 may include a level 1 (L1) cache (216-1) (generally referred to herein as “L1 cache 216”). Various components of the processor 202-1 may communicate with the cache 208 directly, through a bus (e.g., the bus 212), and/or a memory controller or hub.

As shown in FIG. 5, memory 214 may be coupled to other components of system 200 through a memory controller 220. Memory 214 may include volatile memory and may be interchangeably referred to as main memory or system memory. Even though the memory controller 220 is shown to be coupled between the interconnection 204 and the memory 214, the memory controller 220 may be located elsewhere in system 200. For example, memory controller 220 or portions of it may be provided within one of the processors 202 in some embodiments. Alternatively, memory 214 may include byte-addressable non-volatile memory such as INTEL OPTANE technology.

The system 200 may communicate with other devices/systems/networks via a network interface 228 (e.g., which is in communication with a computer network and/or the cloud 229 via a wired or wireless interface). For example, the network interface 228 may include an antenna (not shown) to wirelessly (e.g., via an Institute of Electrical and Electronics Engineers (IEEE) 802.11 interface (including IEEE 802.11a/b/g/n/ac, etc.), cellular interface, 3G, 4G, LTE, BLUETOOTH, etc.) communicate with the network/cloud 229.

System 200 may also include a storage device such as a storage device 230 coupled to the interconnect 204 via storage controller 225. Hence, storage controller 225 may control access by various components of system 200 to the storage device 230. Furthermore, even though storage controller 225 is shown to be directly coupled to the interconnection 204 in FIG. 10, storage controller 225 can alternatively communicate via a storage bus/interconnect (such as the SATA

(Serial Advanced Technology Attachment) bus, Peripheral Component Interconnect (PCI) (or PCI EXPRESS (PCIe) interface), NVM EXPRESS (NVMe), Serial Attached SCSI (SAS), Fiber Channel, etc.) with one or more other components of system 200 (for example where the storage bus is coupled to interconnect 204 via some other logic like a bus bridge, chipset, etc.) Additionally, storage controller 225 may be incorporated into memory controller logic or provided on a same integrated circuit (IC) device in various embodiments (e.g., on the same circuit board device as the storage device 230 or in the same enclosure as the storage device 230).

Furthermore, storage controller 225 and/or storage device 230 may be coupled to one or more sensors (not shown) to receive information (e.g., in the form of one or more bits or signals) to indicate the status of or values detected by the one or more sensors. These sensor(s) may be provided proximate to components of system 200 (or other computing systems discussed herein), including the cores 206, interconnections 204 or 212, components outside of the processor 202, storage device 230, SSD bus, SATA bus, storage controller 225, etc., to sense variations in various factors affecting power/thermal behavior of the system/platform, such as temperature, operating frequency, operating voltage, power consumption, and/or inter-core communication activity, etc.

Any of the memory and/or storage devices in the system 200 may include 3D NAND memory with memory cells having flat trap base profiles, as described herein. In particular, the system 200 may include the processors 202 and a 3D memory device (e.g., memory 214, storage device 230, etc.) coupled to the processors 102, where the 3D memory device includes a substrate with alternated layers of conductor material and insulator material, a memory array of vertical 3D NAND strings formed in the substrate, wherein a pillar of the vertical 3D NAND strings passes through the alternated layers of the substrate, an edge of the layers of insulator material abuts an edge of the pillar, and respective memory cells on the pillar are disposed in respective layers of conductor material between respective layers of the insulator material.

A memory cell of the 3D memory device may include a control gate disposed in a recess of the layer of conductor material between two layers of the insulator material, a trap base disposed in the recess between the control gate and the edge of the pillar, and tunnel oxide material that covers the trap base and extends into the pillar outside of the recess and beyond the edge of the two layers of insulator material. For example, a cross section taken through a center line axis of the pillar and a center of the memory cell has a substantially flat front line for the trap base parallel to the pillar. Material adjacent to the edge of the pillar may have a waviness with a range of variation for the vertical channel that is less than eight percent and a mean of variation for the vertical channel that is less than six percent. For example, a RWB gain for the memory cell may be in a range of between 200 millivolts and 500 millivolts. In some embodiments, the pillar tapers to a neck with a pinch point that is at least seventy five percent as wide a width of the pillar at a line perpendicular to the center axis line of the pillar and through a center of a memory cell on the pillar that is nearest to the pinch point. For example, a control gate voltage minus a threshold voltage of a programmed memory cell within the pillar may be in a range of between 300 millivolts and 450 millivolts.

### Additional Notes and Examples

Example 1 includes an apparatus, comprising a substrate with alternated layers of conductor material and insulator material, a vertical channel through at least four of the alternated layers of the substrate, wherein an edge of the layers of insulator material abuts an edge of the vertical channel, and a memory cell on the vertical channel disposed in a layer of conductor material between two layers of the insulator material, wherein the memory cell comprises a control gate disposed in a recess of the layer of conductor material between the two layers of the insulator material, a trap base disposed in the recess between the control gate and the edge of the vertical channel, and tunnel oxide material that covers the trap base and extends into the vertical channel outside of the recess and beyond the edge of the two layers of insulator material.

Example 2 includes the apparatus of Example 1, wherein a cross section taken through a center line axis of the vertical channel and a center of the memory cell has a substantially flat front line for the trap base parallel to the vertical channel.

Example 3 includes the apparatus of Example 2, wherein material adjacent to the edge of the vertical channel has a waviness with a range of variation for the vertical channel that is less than eight percent and a mean of variation for the vertical channel that is less than six percent.

Example 4 includes the apparatus of Example 3, wherein a read window budget gain for the memory cell is in a range of between 200 millivolts and 500 millivolts.

Example 5 includes the apparatus of any of Examples 2 to 4, wherein material adjacent to outside edges of the vertical channel tapers to a pinch point that is at least seventy five percent as wide a width of the material adjacent to outside edges of the vertical channel at a line perpendicular to the center axis line of the vertical channel and through a center of a memory cell on the vertical channel that is nearest to the pinch point.

Example 6 includes the apparatus of Example 5, wherein a control gate voltage minus a threshold voltage of a programmed memory cell within the vertical channel is in a range of between 300 millivolts and 450 millivolts.

Example 7 includes a method, comprising forming a substrate with four or more alternating layers of conductor material and insulator material, forming a vertical channel through at least four of the alternating layers of the substrate, forming respective recesses in the layers of conductor material adjacent to the vertical channel and between respective layers of insulator material such that an edge of the layers of insulator material abuts an edge of the vertical channel and an edge of the layers of conductor material is spaced away from the edge of the vertical channel, forming respective control gates of memory cells in the recesses next to the edge of the layers of conductor material, forming respective trap bases of the memory cells in the recesses between the respective control gates and the edge of the vertical channel, and covering the respective trap bases and the edge of the layers of insulator material with tunnel oxide material that extends from the respective recesses into the vertical channel beyond the edge of the layers of insulator material.

Example 8 includes the method of Example 7, further comprising depositing the tunnel oxide material over the respective trap bases, outside of the respective recesses, and beyond the edge of the layers of insulator material.

Example 9 includes the method of Example 8, further comprising depositing the tunnel oxide material over the respective trap bases, outside of the respective recesses, and beyond the edge of the layers of insulator material by atomic layer deposition.

Example 10 includes the method of Example 7, further comprising depositing polysilicon material over the respective trap bases, and oxidizing the polysilicon material deposited over the respective trap bases to form the tunnel oxide material that extends into the vertical channel beyond the edge of the layers of insulator material.

Example 11 includes the method of Example 10, further comprising depositing the polysilicon material over the respective trap bases by selective polysilicon deposition.

Example 12 includes the method of any of Examples 7 to 11, further comprising forming the respective trap bases such that a cross section taken through a center line axis of the vertical channel and a center of a memory cell has a substantially flat front line for the trap base of the memory cell parallel to the vertical channel.

Example 13 includes the method of any of Examples 7 to 12, further comprising forming the vertical channel such that the edge of the vertical channel has a waviness with a range of variation for the vertical channel that is less than eight percent and a mean of variation for the vertical channel that is less than six percent.

Example 14 includes the method of any of Examples 7 to 13, further comprising forming the vertical channel such that the vertical channel tapers to a neck with a pinch point that is at least seventy five percent as wide a width of the vertical channel at a line perpendicular to the center axis line of the vertical channel and through a center of a memory cell on the vertical channel that is nearest to the pinch point.

Example 15 includes a system, comprising a processor and a three-dimensional (3D) memory device coupled to the processor, wherein the 3D memory device includes a substrate with alternated layers of conductor material and insulator material, a memory array of vertical 3D NAND strings formed in the substrate, wherein a pillar of the vertical 3D NAND strings passes through the alternated layers of the substrate, an edge of the layers of insulator material abuts an edge of the pillar, and respective memory cells on the pillar are disposed in respective layers of conductor material between respective layers of the insulator material, and wherein a memory cell comprises a control gate disposed in a recess of the layer of conductor material between two layers of the insulator material, a trap base disposed in the recess between the control gate and the edge of the pillar, and tunnel oxide material that covers the trap base and extends into the pillar outside of the recess and beyond the edge of the two layers of insulator material.

Example 16 includes the system of Example 15, wherein a cross section taken through a center line axis of the pillar and a center of the memory cell has a substantially flat front line for the trap base parallel to the pillar.

Example 17 includes the system of Example 16, wherein material adjacent to the edge of the pillar has a waviness with a range of variation for the vertical channel that is less than eight percent and a mean of variation for the vertical channel that is less than six percent.

Example 18 includes the system of Example 17, wherein a read window budget gain for a memory cell is in a range of between 200 millivolts and 500 millivolts.

Example 19 includes the system of any of Examples 16 to 18, wherein the pillar tapers to a neck with a pinch point that is at least seventy five percent as wide a width of the pillar at a line perpendicular to the center axis line of the pillar and through a center of a memory cell on the pillar that is nearest to the pinch point.

Example 20 includes the system of Example 19, wherein a control gate voltage minus a threshold voltage of a programmed memory cell within the pillar is in a range of between 300 millivolts and 450 millivolts.

Example 21 includes an apparatus, comprising means for forming a substrate with four or more alternating layers of conductor material and insulator material, means for forming a vertical channel through at least four of the alternating layers of the substrate, means for forming respective recesses in the layers of conductor material adjacent to the vertical channel and between respective layers of insulator material such that an edge of the layers of insulator material abuts an edge of the vertical channel and an edge of the layers of conductor material is spaced away from the edge of the vertical channel, means for forming respective control gates of memory cells in the recesses next to the edge of the layers of conductor material, means for forming respective trap bases of the memory cells in the recesses between the respective control gates and the edge of the vertical channel, and means for covering the respective trap bases and the edge of the layers of insulator material with tunnel oxide material that extends from the respective recesses into the vertical channel beyond the edge of the layers of insulator material.

Example 22 includes the apparatus of Example 21, further comprising means for depositing the tunnel oxide material over the respective trap bases, outside of the respective recesses, and beyond the edge of the layers of insulator material.

Example 23 includes the apparatus of Example 22, further comprising means for depositing the tunnel oxide material over the respective trap bases, outside of the respective recesses, and beyond the edge of the layers of insulator material by atomic layer deposition.

Example 24 includes the apparatus of Example 21, further comprising means for depositing polysilicon material over the respective trap bases, and means for oxidizing the polysilicon material deposited over the respective trap bases to form the tunnel oxide material that extends into the vertical channel beyond the edge of the layers of insulator material.

Example 25 includes the apparatus of Example 24, further comprising means for depositing the polysilicon material over the respective trap bases by selective polysilicon deposition.

Example 26 includes the apparatus of any of Examples 21 to 25, further comprising means for forming the respective trap bases such that a cross section taken through a center line axis of the vertical channel and a center of a memory cell has a substantially flat front line for the trap base of the memory cell parallel to the vertical channel.

Example 27 includes the apparatus of any of Examples 21 to 26, further comprising means for forming the vertical channel such that the edge of the vertical channel has a waviness with a range of variation for the vertical channel that is less than eight percent and a mean of variation for the vertical channel that is less than six percent.

Example 28 includes the apparatus of any of Examples 21 to 27, further comprising means for forming the vertical channel such that the vertical channel tapers to a neck with a pinch point that is at least seventy five percent as wide a width of the vertical channel at a line perpendicular to the center axis line of the vertical channel and through a center of a memory cell on the vertical channel that is nearest to the pinch point.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrase “one or more of A, B, and C” and the phrase “one or more of A, B, or C” both may mean A; B; C; A and B; A and C; B and C; or A, B and C. Various components of the systems described herein may be implemented in software, firmware, and/or hardware and/or any combination thereof. For example, various components of the systems or devices discussed herein may be provided, at least in part, by hardware of a computing SoC such as may be found in a computing system such as, for example, a smart phone. Those skilled in the art may recognize that systems described herein may include additional components that have not been depicted in the corresponding figures. For example, the systems discussed herein may include additional components such as bit stream multiplexer or de-multiplexer modules and the like that have not been depicted in the interest of clarity.

While implementation of the example processes discussed herein may include the undertaking of all operations shown in the order illustrated, the present disclosure is not limited in this regard and, in various examples, implementation of the example processes herein may include only a subset of the operations shown, operations performed in a different order than illustrated, or additional operations.

In addition, any one or more of the operations discussed herein may be undertaken in response to instructions provided by one or more computer program products. Such program products may include signal bearing media providing instructions that, when executed by, for example, a processor, may provide the functionality described herein. The computer program products may be provided in any form of one or more machine-readable media. Thus, for example, a processor including one or more graphics processing unit(s) or processor core(s) may undertake one or more of the blocks of the example processes herein in response to program code and/or instructions or instruction sets conveyed to the processor by one or more machine-readable media. In general, a machine-readable medium may convey software in the form of program code and/or instructions or instruction sets that may cause any of the devices and/or systems described herein to implement at least portions of the operations discussed herein and/or any portions the devices, systems, or any module or component as discussed herein.

As used in any implementation described herein, the term “module” refers to any combination of software logic, firmware logic, hardware logic, and/or circuitry configured to provide the functionality described herein. The software may be embodied as a software package, code and/or instruction set or instructions, and “hardware”, as used in any implementation described herein, may include, for example, singly or in any combination, hardwired circuitry, programmable circuitry, state machine circuitry, fixed function circuitry, execution unit circuitry, and/or firmware that stores instructions executed by programmable circuitry. The modules may, collectively or individually, be embodied as circuitry that forms part of a larger system, for example, an integrated circuit (IC), system on-chip (SoC), and so forth.

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as IP cores may be stored on a tangible, machine readable medium and supplied to various customers or manufacturing facilities to load into the fabrication machines that actually make the logic or processor.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the embodiments are not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a substrate with alternated layers of conductor material and insulator material;
a vertical channel through at least four of the alternated layers of the substrate, wherein an edge of the layers of insulator material abuts an edge of the vertical channel; and
a memory cell on the vertical channel disposed in a layer of conductor material between two layers of the insulator material, wherein the memory cell comprises:
a control gate disposed in a recess of the layer of conductor material between the two layers of the insulator material,
a trap base disposed in the recess between the control gate and the edge of the vertical channel, and
tunnel oxide material that covers the trap base and extends into the vertical channel outside of the recess and beyond the edge of the two layers of insulator material.

2. The apparatus of claim 1, wherein a cross section taken through a center line axis of the vertical channel and a center of the memory cell has a substantially flat front line for the trap base parallel to the vertical channel.

3. The apparatus of claim 2, wherein material adjacent to the edge of the vertical channel has a waviness with no substantial range of variation between peaks and valleys of the material.

4. The apparatus of claim 3, wherein a read window budget gain for the memory cell is in a range of between 200 millivolts and 500 millivolts.

5. The apparatus of claim 4, wherein material adjacent to outside edges of the vertical channel tapers to a pinch point and a tunnel oxide within the vertical channel is formed such that a variation of oxide thickness across memory cells is insignificant.

6. The apparatus of claim 5, wherein a control gate voltage minus a threshold voltage of a programmed memory cell within the vertical channel is in a range of between 300 millivolts and 450 millivolts.

7. A method, comprising:
forming a substrate with four or more alternating layers of conductor material and insulator material;
forming a vertical channel through at least four of the alternating layers of the substrate;
forming respective recesses in the layers of conductor material adjacent to the vertical channel and between respective layers of insulator material such that an edge of the layers of insulator material abuts an edge of the vertical channel and an edge of the layers of conductor material is spaced away from the edge of the vertical channel;
forming respective control gates of memory cells in the recesses next to the edge of the layers of conductor material;
forming respective trap bases of the memory cells in the recesses between the respective control gates and the edge of the vertical channel; and
covering the respective trap bases and the edge of the layers of insulator material with tunnel oxide material that extends from the respective recesses into the vertical channel beyond the edge of the layers of insulator material.

8. The method of claim 7, further comprising:
depositing the oxide material over the respective trap bases, outside of the respective recesses, and beyond the edge of the layers of insulator material.

9. The method of claim 8, further comprising:
depositing the oxide material over the respective trap bases, outside of the respective recesses, and beyond the edge of the layers of insulator material by atomic layer deposition.

10. The method of claim 9, further comprising:
depositing polysilicon material over the respective trap bases; and
oxidizing the polysilicon material deposited over the respective trap bases to form the tunnel oxide material that extends into the vertical channel beyond the edge of the layers of insulator material.

11. The method of claim 10, further comprising:
depositing the polysilicon material over the respective trap bases by selective polysilicon deposition.

12. The method of claim 11, further comprising:
forming the respective trap bases such that a cross section taken through a center line axis of the vertical channel and a center of a memory cell has a substantially flat front line for the trap base of the memory cell parallel to the vertical channel.

13. The method of claim 12, further comprising:
forming the vertical channel such that the edge of the vertical channel has a waviness with no substantial range of variation between peaks and valleys of the edge of the vertical channel.

14. The method of claim 13, further comprising:
forming the vertical channel such that the vertical channel tapers to a neck with a pinch point; and
forming a tunnel oxide within the vertical channel such that a variation of oxide thickness across memory cells is insignificant.

15. A system, comprising:
a processor and a three-dimensional (3D) memory device coupled to the processor, wherein the 3D memory device includes:
a substrate with alternated layers of conductor material and insulator material;
a memory array of vertical 3D NAND strings formed in the substrate, wherein a pillar of the vertical 3D NAND strings passes through the alternated layers of the substrate, an edge of the layers of insulator material abuts an edge of the pillar, and respective memory cells on the pillar are disposed in respective layers of conductor material between respective layers of the insulator material, and wherein a memory cell comprises:
a control gate disposed in a recess of the layer of conductor material between two layers of the insulator material,
a trap base disposed in the recess between the control gate and the edge of the pillar, and
tunnel oxide material that covers the trap base and extends into the pillar outside of the recess and beyond the edge of the two layers of insulator material.

16. The system of claim 15, wherein a cross section taken through a center line axis of the pillar and a center of the memory cell has a substantially flat front line for the trap base parallel to the pillar.

17. The system of claim 16, wherein material adjacent to the edge of the pillar has a waviness with no substantial range of variation between peaks and valleys of the material.

18. The system of claim 17, wherein a read window budget gain for a memory cell is in a range of between 200 millivolts and 500 millivolts.

19. The system of claim 18, wherein the pillar tapers to a neck with a pinch point and a tunnel oxide within the vertical channel is formed such that a variation of oxide thickness across memory cells is insignificant.

20. The system of claim 19, wherein a control gate voltage minus a threshold voltage of a programmed memory cell within the pillar is in a range of between 300 millivolts and 450 millivolts.
